(19) United States
(12) Patent Application Publication
(10) Pub. No.: US 2025/0052815 A1
(43) Pub. Date: Feb. 13, 2025

(54) CIRCUIT ARRANGEMENT FOR CHECKING THE CUTOUT ABILITY OF AN ELECTRONIC SWITCH

(71) Applicant: Continental Automotive Technologies GmbH, Hannover (DE)

(72) Inventors: Erwin Kessler, Saulgau (DE); Christian Gil, Toulouse (FR)

(73) Assignee: Continental Automotive Technologies GmbH, Hannover (DE)

(21) Appl. No.: 18/722,965

(22) PCT Filed: Dec. 16, 2022
(86) PCT No.: PCT/DE2022/200304

§ 371 Date: Jun. 21, 2024

(30) Foreign Application Priority Data
Dec. 23, 2021 (DE) 10 2021 214 975.8

(51) Int. Cl. G01R 31/327

(52) U.S. Cl. CPC G01R 31/3275; G01R 31/3277

(57) ABSTRACT

Disclosed is a circuit arrangement for checking the cutout ability of an electronic fuse used as an interrupter, a first electronic switch, between a power supply and a control device. A second electronic switch is connected in parallel with the first switch has a lower current-carrying capacity than the first switch and is configured, when conductive, to generate a lower voltage drop across its load path than the first switch at the same current as the first switch. The first and the second switches are actuated by a control and diagnostic circuit configured to check the cutout ability of the first switch acting as a fuse when the second switch is switched on, and to check the voltage drop across the two switches and, upon a reduction in the voltage when the second switch is on and the first switch is off, to conclude that the switches are functioning correctly.

In present-day power supply architectures of vehicles, electronic control devices that are supplied with current even during a parking mode of the vehicle are supplied directly from the 12 V vehicle battery. In this case, the cabling between battery and control devices is at present usually protected by fusible links.

Driven by the supply demand e.g. of autonomous driving, the fusible links are frequently being replaced by electronic fuses, often referred to as e-fuses.

The electronic fuses are typically realized by means of electronic switches in the form of MOSFETs. The MOSFET control can be part of an intelligent network switch or can be realized by means of specific integrated circuits (ICs) supplemented by discrete circuit blocks.

In this case, it is possible and customary for the electronic fuses to supply diagnosis information such as the current through the switch, the temperature of the switch and further useful information. All this information is predominantly made available while an electronic fuse is in the closed state.

One item of information that is often missing is whether a closed electronic fuse can be opened if the situation would necessitate opening.

In the case of a fusible link the failure state of the fuse device is an open fuse, while in the case of an electronic fuse a defect of the switching element can result in a closed switch. This would have the effect that in the case of an event that would necessitate the opening of the fuse, this opening cannot be realized on account of the defect of the electronic fuse.

In principle, it would be possible to switch off an electronic fuse in specific situations in order to check whether the turn-off capability is still provided. In the case of some critical control devices that are supplied via an electronic fuse, interrupting the supply for a specific time is not allowed, however.

The object of the invention is to specify a circuit arrangement for checking the turn-off capability of an electronic switch in which a control device is continuously supplied with power.

The object is achieved by means of a circuit arrangement as claimed in claim 1. Advantageous developments are specified in the dependent claims.

Accordingly, in a circuit arrangement for checking the turn-off capability of an electronic fuse in the form of a first electronic switch, said electronic fuse being used as an interrupter switch between a voltage supply and at least one control device, a second electronic switch is connected in parallel with the first electronic switch, said second electronic switch having a lower current-carrying capacity than the first electronic switch and being configured,
a) to supply the connected control devices if the latter are in an operating mode with reduced current consumption,
b) in the case of a defect to limit its current to a value which does not have a critical influence on a vehicle battery serving as voltage supply,
c) in the case where it is turned on, to generate a smaller voltage drop across its load path than the first electronic switch if it carries the same current as the first electronic switch,
wherein the first electronic switch and the second electronic switch are controlled by a control and diagnosis circuit, controlled by a control unit configured to check the first electronic switch, functioning as a fuse, with regard to its turn-off capability if the second electronic switch is switched on,
wherein it switches on the second electronic switch before the first electronic switch is switched off and the first electronic switch is switched on before the second electronic switch is switched off, and
wherein the control and diagnosis circuit is configured to check the voltage drop across the two electronic switches and to deduce a correct function of the electronic switches in the case of a reduction of the voltage when the second electronic switch is switched on and the first electronic switch is switched off.

As a result of the second electronic switch being provided, the operation of connected control devices can advantageously be maintained if the turn-off capability of the first electronic switch is checked.

In one advantageous embodiment of the circuit arrangement, the two electronic switches are embodied as MOSFETs.

In an advantageous manner, the turn-off capability of the first electronic switch is checked in time ranges in which the control device does not have a high current demand.

The invention will be described in greater detail below on the basis of an exemplary embodiment with the aid of figures. Here in the figures:

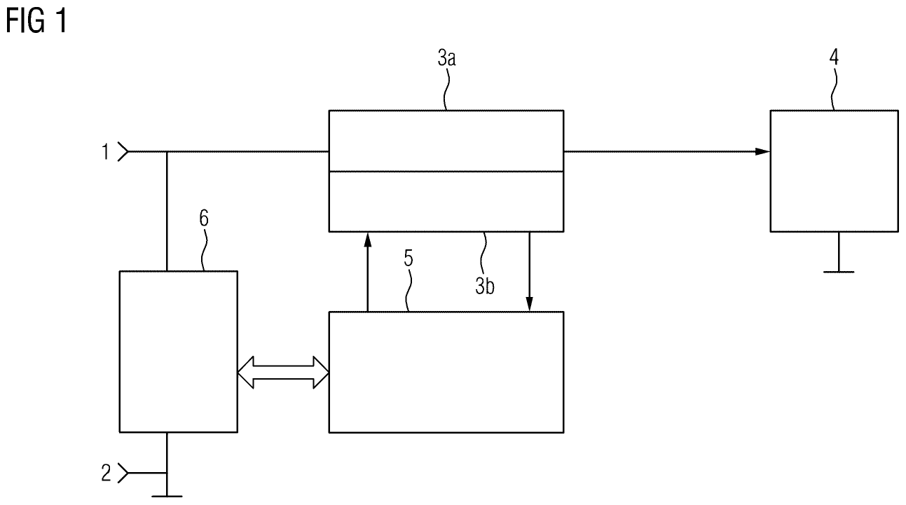

FIG. 1 shows a basic circuit diagram of a control device which is protected by means of an electronic fuse and which is supplied from a voltage supply source,

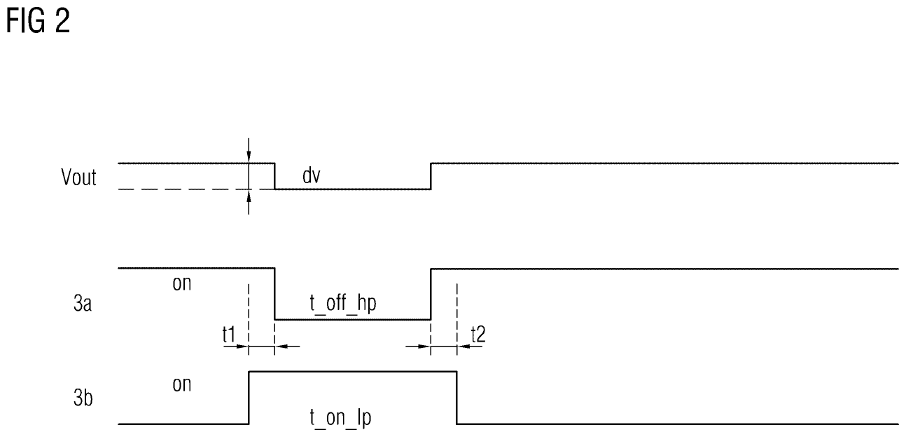

FIG. 2 shows a profile of the switching states of the two electronic switches.

FIG. 1 schematically shows two connecting terminals 1, 2 for a voltage source, for example a 12-volt battery in a motor vehicle. The connecting terminal 1 for the positive pole of the voltage source is connected to a control device 4 via an electronic fuse.

The electronic fuse is embodied with a first electronic switch 3a, preferably formed as a MOSFET, and during normal operation, in which the control device 4 is supplied by the voltage source, is fully turned on in order to minimize the on-state resistance of the MOSFET—usually designated as R_{DSon}.

The control device 4 is of a type which must not be completely disconnected from the voltage supply, such that checking the turn-off capability of the first electronic switch 3a by completely opening the latter is not considered as a straightforward possibility.

Therefore, a second electronic switch 3b, which is likewise preferably embodied as a MOSFET, is connected in parallel with the first electronic switch 3a. Said second electronic switch can be switched on before the first electronic switch 3a can be switched off, such that a permanent power supply of connected control devices 4 is ensured.

In the exemplary embodiment illustrated, the two electronic switches are controlled by a control and diagnosis circuit 5, which is in turn controlled by a control unit 6.

The second electronic switch 3b has a lower current-carrying capacity than the first electronic switch 3a and is configured to supply the connected control devices 4 if the latter are in an operating mode with reduced current consumption. It additionally has the capability, in the case of a defect, of limiting its current to a value which does not have a critical influence on a vehicle battery serving as voltage supply. In addition, in the case where it is turned on, it generates a smaller voltage drop across its load path than the first electronic switch 3a if it carries the same current as the first electronic switch 3a.

This reduced voltage can be detected by the control and diagnosis circuit 5 and is an indication that the first electronic switch 3a is no longer conductively switched, i.e. is able to be switched off completely and can thus fulfill its function as a fuse.

FIG. 2 illustrates state profiles of the two electronic switches 3a, 3b and the profile of the voltage across the two electronic switches 3a, 3b. The second electronic switch 3b is switched on at a point in time t1 and the first electronic switch 3a is switched off a short time period later. As a result, the voltage drop across the two switches 3a, 3b connected in parallel decreases by an amount dV, which can be detected by the control and diagnosis circuit 5. The first electronic switch 3a is switched on again at a later point in time and the second electronic switch 3b is switched off again a short time period later, at a point in time t2. The test phase is then ended.

The turn-off capability test is carried out in a vehicle status with limited current demand at the output of the electronic fuse 3. This may be e.g. in the phase in which the supplied control device 4 is still in operation, but does not activate any current-consuming loads. In this status, the current consumption of the control device 4 provides for a rapid voltage drop phase during the switching capability test and limits the power loss of the MOSFET during the linear load.

Ideally, communication network-based power management defines events for the turn-off capability test on the basis of the gathered information about the vehicle status and the status of the supplied control devices.

1. A circuit arrangement for checking the turn-off capability of an electronic fuse in the form of a first electronic switch, said electronic fuse being used as an interrupter switch between a voltage supply and at least one control device, comprising:
a second electronic switch connected in parallel with the first electronic switch, said second electronic switch having a lower current-carrying capacity than the first electronic switch and configured to
supply the connected control devices if the latter are in an operating mode with reduced current consumption,
in case of a defect to limit the second electronic switch's current to a value which does not have a critical influence on a vehicle battery serving as voltage supply,
in case where the second electronic switch is turned on, to generate a smaller voltage drop across the second electronic switch's load path than the first electronic switch when the second electronic switch carries the same current as the first electronic switch,
wherein the first electronic switch and the second electronic switch are controlled by a control and diagnosis circuit, controlled by a control unit configured to check the first electronic switch, functioning as a fuse, with regard to the first electronic switch's turn-off capability if the second electronic switch is switched on,
wherein the circuit arrangement switches on the second electronic switch before the first electronic switch is switched off and the first electronic switch is switched on before the second electronic switch is switched off, and wherein the control and diagnosis circuit is configured to check the voltage drop across the two electronic switches and to deduce a correct function of the electronic switches in the case of a reduction of the voltage when the second electronic switch is switched on and the first electronic switch is switched off.

2. The circuit arrangement as claimed in claim 1, wherein the two electronic switches are embodied as MOSFETs.

3. The circuit arrangement as claimed in claim 1, wherein the turn-off capability of the first electronic switch is checked in time ranges in which the control device does not have a high current demand.

4. The circuit arrangement as claimed in claim 2, wherein the turn-off capability of the first electronic switch is checked in time ranges in which the control device does not have a high current demand.
